(19) United States
(12) Patent Application Publication
(10) Pub. No.: US 2005/0067954 A1
(43) Pub. Date: Mar. 31, 2005

(54) Organic EL panel

(76) Inventors: Ryuji Nishikawa, Gifu-shi (JP); Tetsuji Omura, Ogaki-shi (JP)

Correspondence Address: CANTOR COLBURN, LLP, 55 GRIFFIN ROAD SOUTH, BLOOMFIELD, CT, 06002, US

(21) Appl. No.: 10/954,092

(22) Filed: Sep. 29, 2004

(30) Foreign Application Priority Data
Sep. 30, 2003 (JP) 2003-342664

(51) Int. Cl. H05B 33/00

(52) U.S. Cl. 313/506; 313/501

(57) ABSTRACT

A semi-transmissive film is provided underneath a transparent electrode of an organic EL element for a specific color. The optical length of the interval between the upper surface of the semi-transmissive film and the lower surface of a counter electrode serving as a reflective layer is configured such that this interval functions as a microresonator for selecting light having a specific wavelength. In an organic EL element for another color, the semi-transmissive film is omitted. According to this arrangement, emissive efficiency of an organic EL element for a color naturally having low emissive efficiency can be selectively enhanced.

### CROSS-REFERENCE TO RELATED APPLICATIONS

The priority Japanese application No. 2003-342664 upon which this patent application is based is hereby incorporated by reference.

### BACKGROUND OF THE INVENTION

1. Field of the Invention

The present invention relates to an organic EL panel formed by arranging a plurality of organic EL elements each comprising an organic layer provided between first and second electrodes and emitting light when a voltage is applied between the first and second electrodes.

2. Description of the Related Art

In recent years, organic electroluminescence (hereinafter referred to as “EL”) displays have gained attention as one type of flat display which would replace liquid crystal displays in the coming generation. In a display panel of an organic EL display (hereinafter referred to as “organic EL panel”), the color of light emitted from each pixel may be determined depending on the emissive material used in the organic emissive layer of each pixel. By allowing the pixels to emit light of different colors using different emissive materials, RGB indication can be achieved.

However, when employing this method, the panel manufacturing process becomes difficult and complex because measures must be effected to compensate for differences in emissive efficiency of the emissive materials for different colors, and steps for applying different emissive materials to corresponding pixels must be carried out separately.

In order to achieve full color indication, other methods for determining pixel colors are proposed. In such methods, light of a single color alone is initially emitted, and color filters or color conversion layers are employed to obtain light of other colors. However, according to these methods, it is difficult to achieve sufficient emissive efficiency for each color.

Another alternative method using microcavities is disclosed in the following document: Takahiro NAKAYAMA and Atsushi KADOTA, “Element Incorporating Optical Resonator Structure, Third Meeting (1993)”, in “From the Basics to the Frontiers in the Research of Organic EL Materials and Devices”, Dec. 16 and 17, 1993, Tokyo University Sanjo Conference Hall, Japan Society of Applied Physics, Organic Molecular Electronics and Bioelectronics Division, JSAP Catalog Number AP93 2376, p. 135-143. According to this method, a microcavity which functions as a microresonator is provided in each pixel to extract light having a specific wavelength. Using this microresonator, light having a specific wavelength can be selectively intensified.

According to the conventional method using microcavities, it is necessary to change the optical length of the microresonator indifferent emissive elements according to color. Because of this requirement, it was difficult to manufacture a panel having a large number of pixels.

### SUMMARY OF THE INVENTION

The present invention provides an organic EL panel with microresonators that can be manufactured easily.

According to the present invention, with respect to a specific color, a microresonator (microcavity) is configured with an organic emissive layer and a transparent electrode disposed between a counter electrode and a semi-transmissive film. Accordingly, in an organic EL element for the specific color, light ejected through the semi-transmissive film is limited to a specific wavelength while the specific wavelength is intensified. On the other hand, no microresonator is formed for an organic EL element for another color. As a result, in the EL element without microresonator, light generated in the organic layer is ejected without further processing.

By employing a panel configuration in which a semi-transmissive film is omitted to avoid forming a microresonator in certain organic EL elements, the structure concerning optical length in an EL element without microresonator can be made identical with that of an EL element having a microresonator, except for the omission of the semi-transmissive film. A panel having such a configuration can be manufactured easily.

### BRIEF DESCRIPTION OF THE DRAWINGS

FIG. 1 is a cross-sectional view showing a configuration of a pixel portion of an organic EL panel.

FIG. 2 shows an example configuration of organic EL elements for the respective colors of R, G, and B, according to the present invention.

FIG. 3 shows a configuration of an organic EL element which emits white light.

FIG. 4 shows an example configuration for the respective colors of R, G, and B using white-emitting organic EL elements, according to the present invention.

FIG. 5 is a diagram showing an example spectrum of a white-emitting organic EL element.

FIG. 6 shows an example configuration of a white-emitting organic EL element having a top-emission structure.

FIGS. 7-10 are schematic diagrams showing example configurations in which microresonators are provided depending on colors of pixels.

### DESCRIPTION OF THE PREFERRED EMBODIMENTS

Preferred embodiments of the present invention will next be described referring to the drawings.

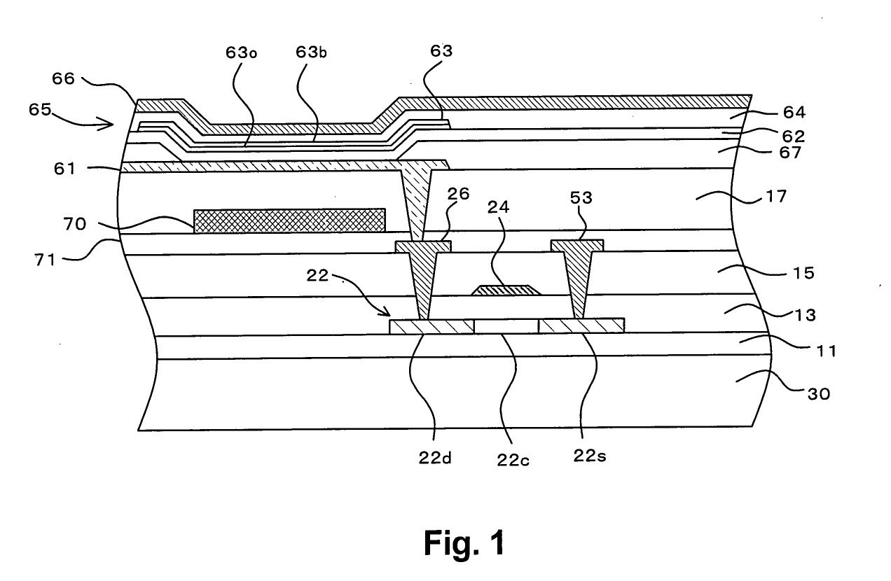

FIG. 1 is a cross-sectional view showing a configuration of a light-emitting region and a drive TFT (thin film transistor) within one pixel. It should be noted that each pixel actually includes a plurality of TFTs. The drive TFT is the TFT which controls a current supplied from a power line to an organic EL element within the pixel. On a glass substrate 30, a buffer layer 11 composed of a lamination of an SiN layer and an SiO₂ layer is formed over the entire surface. Further on top, an active layer 22 made of polysilicon is disposed in predetermined areas (where TFTs are to be created).

Covering the active layer 22 and the buffer layer 11, a gate insulation film 13 is formed over the entire surface. The gate insulation film 13 may be formed by laminating an SiO₂ layer and an SiN layer. On top of the gate insulation film 13 at a position above a channel region 22c, a gate electrode 24 composed of chromium or the like is arranged. Subsequently, impurities are doped into the active layer 22 while using the gate electrode 24 as a mask. As a result of this process, in the active layer 22, the channel region 22c without impurities is provided in the central portion under the gate electrode 24, while a source region 22s and a drain region 22d doped with impurities are formed on both sides of the channel region 22c.

Next, covering the gate insulation film 13 and the gate electrode 24, an interlayer insulation film 15 is formed over the entire surface. Contact holes are then created in the interlayer insulation film 15 at positions corresponding to the source region 22s and the drain region 22d. The source region 22s and the drain region 22d are located under the interlayer insulation film 15. Subsequently, a source electrode 53 and a drain electrode 26 are provided through these contact holes and on the upper surface of the interlayer insulation film 15, so as to connect with the source region 22s and the drain region 22d, respectively. It should be noted that the source electrode 53 is connected to a power line (not shown). While the drive TFT formed as described above is a p-channel TFT in this example, the drive TFT may alternatively be constituted as an n-channel TFT.

Covering the interlayer insulation film 15, source electrode 53, and drain electrode 26, a film 71 of SiN or the like is formed over the entire surface. A color filter 70 is next formed on top of the SiN film 71 at a position corresponding to the light-emitting region in each pixel.

Covering the SiN film 71 and the color filter 70, a planarization film 17 is provided over the entire surface. On the planarization film 17 at the position of the light-emitting region, a semi-transmissive film 69 composed of a thin film of Ag or the like is formed. A transparent electrode 61 which serves as an anode is then disposed on the semi-transmissive film 69. At a position above the drain electrode 26, a contact hole is created through the planarization film 17. Via this contact hole, the drain electrode 26 and the transparent electrode 61 are connected.

While an organic film such as acrylic resin is typically used to form the interlayer insulation film 15 and planarization film 17, it is also possible to employ TEOS or an inorganic film. A metal such as aluminum may be favorably used to create the source electrode 53 and drain electrode 26. For the transparent electrode 61, ITO is typically employed.

The transparent electrode 61 is typically formed in a region covering more than half of the entire area of each pixel. The transparent electrode 61 normally has a substantially rectangular overall shape with a contacting portion protruding laterally and downward through the contact hole for connection with the drain electrode 26. As can be seen in FIG. 1, the semi-transmissive film 69 is formed slightly smaller than the anode 61.

On top of the transparent electrode 61, an organic layer 65 and a counter electrode 66 are arranged. The organic layer 65 comprises a hole transport layer 62 formed over the entire surface, an organic emissive layer 63 formed slightly larger than the light-emitting region, and an electron transport layer 64 formed over the entire surface. The counter electrode 66, which serves as a cathode, is made of metal such as aluminum, and is formed over the entire surface.

At a position on the upper surface of the peripheral portion of the transparent electrode 61 and underneath the hole transport layer 62, a planarization film 67 is provided. The planarization film 67 limits the portion in which the hole transport layer 62 directly contacts the transparent electrode 61, thereby defining the light-emitting region in each pixel. It should be noted that, while an organic film such as acrylic resin is typically used for the planarization film 67, it is also possible to employ TEOS or an inorganic film.

The hole transport layer 62, the organic emissive layer 63, and the electron transport layer 64 are composed of materials that are conventionally used in an organic EL element. The color of emitted light is determined depending on the material (usually the dopant) of the organic emissive layer 63. For example, the hole transport layer 62 maybe composed of NPB, the organic emissive layer 63 for emitting red light may be composed of TBADN+DCJTB, the organic emissive layer 63 for emitting green light may be composed of Alq₃+CFDMQA, the organic emissive layer 63 for emitting blue light may be composed of TBADN+NPB, and the electron transport layer 64 may be composed of Alq₃.

In the above-described arrangement, when the drive TFT is turned on by a voltage set in the gate electrode 24, current from the power line flows from the transparent electrode 61 to the counter electrode 66. This current causes light emission in the organic emissive layer 63. The emitted light passes through the transparent electrode 61, planarization film 17, interlayer insulation film 15, gate insulation film 13, and glass substrate 30, to be ejected downward in FIG. 1.

In the present embodiment, a semi-transmissive film 69 composed of a thin film of silver (Ag) or the like is provided on the underside of the transparent electrode 61 at the position of the light-emitting region. Accordingly, light generated in the organic emissive layer 63 is reflected by the semi-transmissive film 69. Because the counter electrode 66 functions as a reflective layer, the light is repetitively reflected between the semi-transmissive film 69 and the counter electrode 66.

The interval structure between the semi-transmissive film 69 and the counter electrode 66 is configured such that this interval optically functions as a microresonator for a specific color. In other words, the optical length of the interval is set to a value obtained by multiplying the wavelength of a desired color by an integer or a reciprocal of an integer (such as 1/2, 1, and 2). For example, the values of refractive index for the materials constituting each layer in the interval may be approximately as follows: 1.9 for ITO constituting the transparent electrode 61; 1.46 for SiO₂ constituting the gate insulation film 13; 2.0 for SiN also used for the gate insulation film 13; and 1.7 for the organic layer 65 including the organic emissive layer 63. By multiplying the physical thickness of each layer between the semi-transmissive film 69 and the counter electrode 66 by a corresponding refractive index, and then summing the calculated values, the optical thickness of the interval can be obtained. In the present embodiment, this optical thickness is set to a value relative to the wavelength of light to be extracted. With this arrangement, the interval between the semi-transmissive film 69 and the counter electrode 66 functions as a microresonator, and enables efficient extraction of light having a desired wavelength. More specifically, light emitted from the organic emissive layer 63 is repetitively reflected between the semi-transmissive film 69 and the counter electrode 66, and, as a result, light components having a specific wavelength are selectively passed through the semi-transmissive film 69. By further repeating such reflection within the microresonator, the probability that light having the specific wavelength will be ejected can be increased, resulting in enhanced efficiency.

According to the present embodiment, the color filter 70 is arranged in a layer between the interlayer insulation film 15 and the planarization film 17. The color filter 70 may be composed of a material such as a photosensitive resin or polymer having a pigment mixed therein, similarly to color filters used in a liquid crystal display and a CCD camera.

The color filter 70 serves to selectively pass the ejected light so as to limit the wavelength of the obtained light, thereby enabling reliable control of the obtained color. In the present embodiment, because the microresonator limits light passing through the semi-transmissive film 69 as described above, the color filter 70 is not a fundamental requirement and may be omitted.

However, the microresonator basically regulates only the wavelength of light that is incident from a direction perpendicular to the surface of the semi-transmissive film 69. Accordingly, the wavelength of light ejected from the microresonator is highly dependent on the viewing direction, such that different colors are likely to be detected when the panel is viewed at an angle. By providing the color filter 70 as in the present embodiment to pass the ejected light through the color filter 70, the obtained light would unfailingly have a specific wavelength. In this manner, the viewing angle dependency of the panel can be substantially eliminated.

The position of the color filter 70 is not limited to the top of the interlayer insulation film 15. Alternatively, the color filter 70 may be formed on the upper surface or the underside of the glass substrate 30. A light-shielding film is often provided on the upper surface of the glass substrate 30 in order to prevent external light from irradiating on the drive TFT. In such a case, the color filter 70 may be formed in the same layer as the light-shielding film to simplify the manufacturing process.

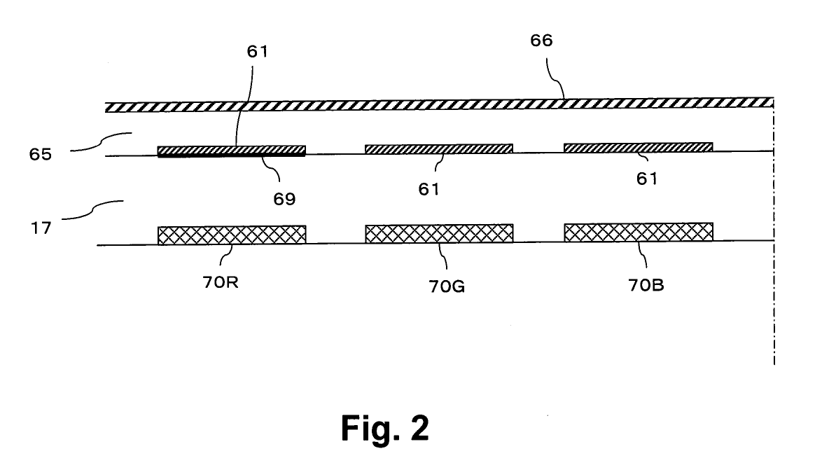

FIG. 2 diagrammatically shows three pixels of R, G, and B. As can be seen, the semi-transmissive film 69 is provided for the pixel of one color alone, while no semi-transmissive film is provided for the pixels of other colors. This arrangement is employed because the interval between the semi-transmissive film 69 and the counter electrode 66 is configured to form a microresonator for the one color alone (red R in the present example). In the pixel for the one color, light of this color is intensified and passed through the semi-transmissive film 69. In the pixels for the other colors, emitted light is ejected downward without further processing by a microresonator.

Light emission of the three colors of RGB can be achieved using different organic materials. However, each organic material has a different emissive efficiency (amount of light emission/current) By employing a microresonator for a pixel of the color having the lowest emissive efficiency so as to intensify the emitted light, a more uniform light emission can be accomplished. Furthermore, the life of organic EL elements can be equalized among different colors because necessary currents for uniform light emission among different colors are equalized.

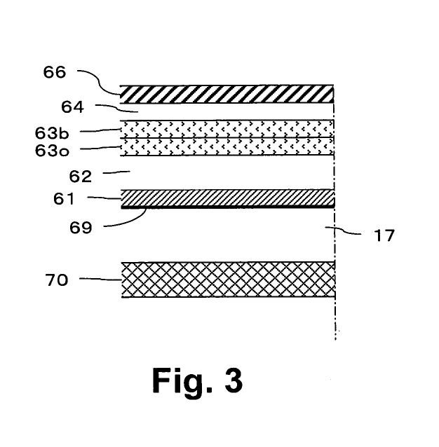

Because the color filters 70 are provided in the present embodiment, the color of light emitted by each pixel can be white. In order to achieve emission of white light, the organic emissive layer 63 may be constituted with a two-layer structure including a blue emissive layer 63b and an orange emissive layer 63o, as shown in FIG. 3. According to this arrangement, holes and electrons combine in regions near the border between the two emissive layers 63b and 63o, thereby generating both blue light and orange light. The light of the two colors in combination are emitted as white light. The orange organic emissive layer 63o may be composed of materials such as NPB+DBzR.

When employing a white organic emissive layer 63 as described above, the organic emissive layer 63 can be formed over the entire surface, without the need to separately perform the emissive layer forming process for the pixels of different colors. The organic emissive material can be simply deposited without using masks. When adopting this configuration, it is preferable to control the thickness of the transparent electrode 61 in order to adjust the optical length of the microresonator. In this manner, all layers disposed above the transparent electrode 61 can be formed over the entire surface without using masks, further facilitating the panel manufacturing process.

In the present embodiment, light of the color having the lowest emissive efficiency among the emitted white light is intensified and selected using a microresonator, and further selected by a color filter 70 to be ejected.

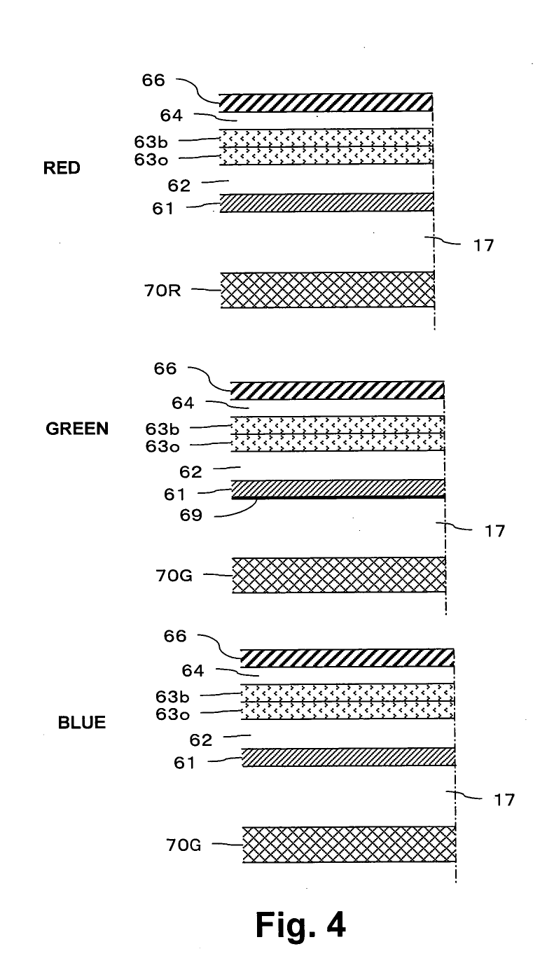

More specifically, as shown in FIG. 4, the distance from the underside of the transparent electrode 61 to the underside of the cathode 66 is identical among all of the pixels. This distance is configured to have an optical length which selects and intensifies light of one color (green G, for example). In the pixel for this one color, the semi-transmissive film 69 is disposed beneath the transparent electrode 60. In the pixels of other colors (red R and blue B, for example), no semi-transmissive film is provided.

According to this arrangement, in the G pixel, the microresonator extracts a specific color (green) from among the emitted white light as described above, and the extracted light is passed and ejected through a green color filter 70. In the R and B pixels, the white light emitted from the organic emissive layer 63 is simply passed through the color filters 70 to be ejected as light of predetermined colors (red and blue, respectively).

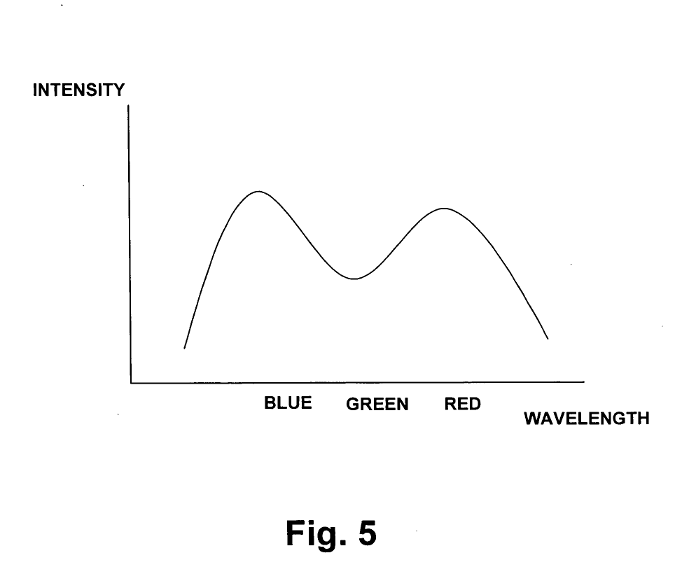

In this embodiment, the only difference among the pixels is whether or not the semi-transmissive film 69 is provided. Further, the optical length can be set easily, and the panel manufacturing process can be very much simplified. Moreover, light for one color can be intensified using the microresonator. When white light obtained by emission of two colors is used, one color among the three primary colors tends to have lower intensity compared to the other two colors. By employing the microresonator for the low-intensity color, a favorable color display can be achieved. For example, when light emission is executed by two emissive layers of blue and orange, the intensity of green light becomes lower than the other colors, as shown in FIG. 5. In order to equalize intensity, the semi-transmissive film 69 is provided for the green pixel so as to configure the microresonator to intensify the green light. In this manner, effective color display can be accomplished.

While the above-described embodiments refer to a bottom emission type panel in which light is ejected via the glass substrate 30, an EL panel according to the present invention may alternatively be configured as top emission type in which light is ejected via the cathode.

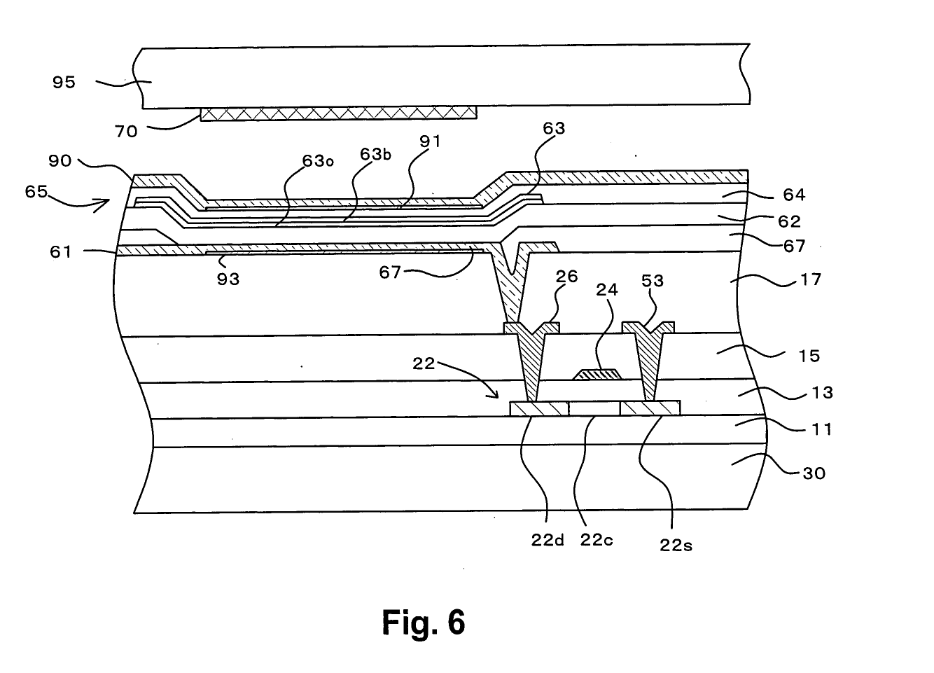

FIG. 6 shows a configuration of a pixel portion of a top emission type panel. In this example, a transparent cathode 90 composed of ITO is employed as the cathode. Further, a semi-transmissive film 91 is disposed on the underside of the transparent cathode 90.

Furthermore, a metal reflective layer 93 is formed under the transparent electrode 61. The interval structure between the surface of the metal reflective layer 93 and the semi-transmissive film 91 functions as the microresonator.

In this embodiment, the color filter 70 is provided on the underside of a sealing substrate 95. It should be noted that the sealing substrate 95 connects to the substrate 30 at its peripheral portion alone, and serves to seal the upper space of the substrate 30 having components such as the organic EL element formed thereon. The top emission structure shown in FIG. 6 can be employed in any of the above-described configurations according to the present invention.

While the TFTs in the above embodiments are described as top gate type TFTs, bottom gate type TFTs may alternatively be used.

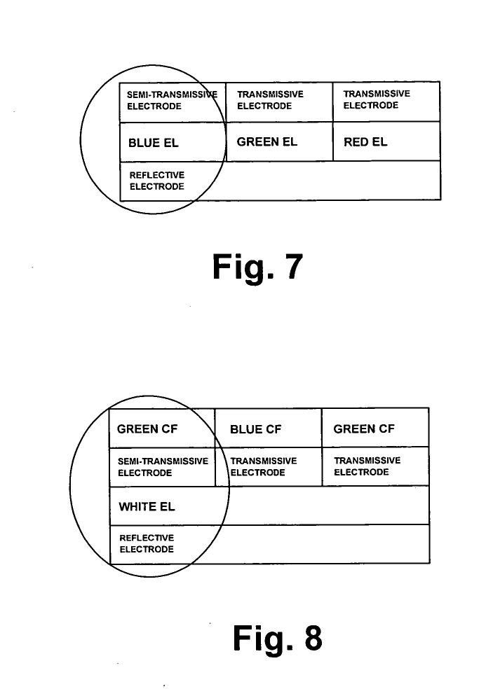

FIGS. 7-10 diagrammatically illustrate example configurations of the present invention. To simplify explanation, only the characteristic structures are shown in these drawings.

FIG. 7 shows an example in which a semi-transmissive electrode (composed of the transparent electrode and the semi-transmissive film) is provided to configure a microresonator (microcavity) for one color alone. In this example, the semi-transmissive electrode is provided to configure the microresonator only in the pixel including a blue organic emissive layer (blue EL). For the green and red organic emissive layers (green EL and red EL), transparent electrodes are provided instead, such that light emitted from the organic emissive layer is ejected without further processing. It should be noted that a reflective electrode is provided covering the entire surface underneath the organic emissive layer. Light emitted from the organic emissive layer is reflected by the reflective electrode and ejected through the transparent electrode.

In FIG. 8, an organic emissive layer which emits white light (white EL) is provided over the entire surface. Further, a semi-transmissive electrode is formed underneath a green color filter (green CF), while transmissive electrodes are disposed under a blue color filter (blue CF) and a red color filter (red CF). In this arrangement, only the green pixel, which outputs green light by way of the green CF, includes a microresonator (microcavity) constituted with the semi-transmissive electrode. Accordingly, in the green pixel, green light within the white light emitted from the white EL is intensified. The overall resulting light is passed through the green CF such that the ejected light is limited to green light. Meanwhile, the white light emitted from the white EL is passed through the blue CF in the blue pixel so as to limit the ejected light to blue light, and through the red CF in the red pixel so as to limit the ejected light to red light, thereby enabling RGB display.

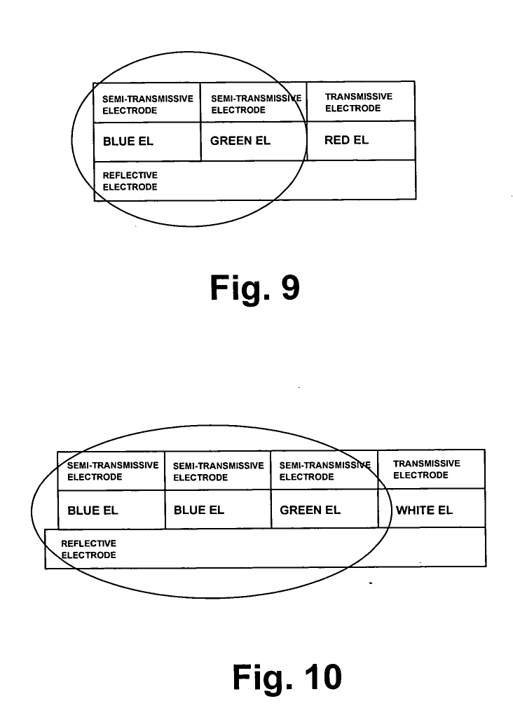

FIG. 9 shows an example in which semi-transmissive electrodes are provided to configure microresonators (microcavities) for two colors, while employing the three colors of blue EL, green EL, and red EL as the organic emissive layer. More specifically, the semi-transmissive electrodes are provided to configure the microresonators in green and blue pixels, while a transmissive electrode is provided in a red pixel so as to allow red light emitted from the organic emissive layer (red EL) to be ejected without further processing.

FIG. 10 shows an example in which semi-transmissive electrodes are provided to configure microresonators (microcavities) for the three colors of RGB, while employing four colors of blue EL, green EL, red EL, and white EL as the organic emissive layer. More specifically, the semi-transmissive electrodes are provided to configure the microresonators in red, green, and blue pixels, while a transmissive electrode is provided in a white pixel so as to allow white light emitted from the organic emissive layer (white EL) to be ejected without further processing.

1. An organic EL panel formed by arranging a plurality of pixels each including an organic EL element, wherein
the organic EL element includes an organic layer provided between first and second electrodes, and emits light when a voltage is applied between the first and second electrodes to allow a current to flow in the organic layer;
the plurality of pixels include pixels for a plurality of colors for ejecting light of colors differing from one another;
a microresonator is provided for a pixel for at least one specific color, the microresonator for repetitively reflecting light emitted from the organic layer within an interval having a predetermined optical length, and thereby intensifying and selecting light having a specific wavelength; and
microresonator is omitted in a pixel for at least another color.

2. An organic EL panel as defined in claim 1, wherein
the plurality of pixels include pixels of three colors of red, green, and blue, and the microresonator is provided for a pixel having the lowest emissive efficiency among the three colors.

3. An organic EL panel as defined in claim 2, wherein
the plurality of pixels include the organic EL elements which emit red, green, and blue light, respectively.

4. An organic EL panel as defined in claim 2, wherein
the plurality of pixels include the organic EL elements which emit white light, and color filters of red, green and blue, respectively.

5. An organic EL panel as defined in claim 1, wherein
the microresonator is configured to repetitively reflect light between a reflective layer and a semi-transmissive layer, so as to eject light having a specific wavelength through the semi-transmissive layer; and
the semi-transmissive layer is provided for an organic EL element in a pixel for a specific color, while semi-transmissive layer is omitted in an organic EL element in a pixel for another color.

6. An organic EL panel as defined in claim 1, wherein the microresonator is configured by providing:
a semi-transmissive layer included in the first electrode, which reflects light emitted from the organic layer; and
a reflective layer included in the second electrode, for reflecting light emitted from the organic layer; wherein
an interval between the reflective layer and the semi-transmissive layer is configured to have the predetermined optical length, such that when light generated in the organic layer is repetitively reflected between the reflective layer and the semi-transmissive layer, the interval between the reflective layer and the semi-transmissive layer functions as the microresonator which intensifies and selects light having a specific wavelength and ejects the selected light through the semi-transmissive layer.

7. An organic EL panel as defined in claim 6, wherein
the first electrode is a laminated structure composed of the semi-transmissive layer and a transparent electrode; and
the second electrode is a metal electrode which functions as the reflective layer.

8. An organic EL panel as defined in claim 7, wherein
among the semi-transmissive layer and the transparent electrode, the transparent electrode is located closer to the organic layer.

9. An organic EL panel as defined in claim 8, wherein
the first electrode is an anode, while the second electrode is a cathode.

10. An organic EL panel as defined in claim 1, wherein the microresonator is configured by providing:
a reflective layer included in the first electrode, for reflecting light emitted from the organic layer; and
a semi-transmissive layer included in the second electrode, which reflects light emitted from the organic layer; wherein
an interval between the reflective layer and the semi-transmissive layer is configured to have a predetermined optical length, such that when light generated in the organic layer is repetitively reflected between the reflective layer and the semi-transmissive layer, the interval between the reflective layer and the semi-transmissive layer functions as the microresonator which intensifies and selects light having a specific wavelength and ejects the selected light through the semi-transmissive layer.

11. An organic EL panel as defined in claim 10, wherein
the first electrode is a laminated structure composed of a metal film which functions as the reflective layer and a transparent electrode; and
the second electrode is a laminated structure composed of the semi-transmissive layer and a transparent electrode.

12. An organic EL panel as defined in claim 1, wherein
a thin film transistor for driving an organic EL element is provided corresponding to each of the plurality of organic EL elements;
the plurality of organic EL elements are formed in a layer located above the corresponding thin film transistors, with a planarization film disposed between the organic EL elements and the thin film transistors; and
a semi-transmissive layer and a color filter are arranged adjacent to respective surfaces of the planarization film.

13. An organic EL panel as defined in claim 1, wherein
the plurality of organic EL elements are formed on a pixel substrate;
a counter substrate is arranged opposing the pixel substrate; and
a color filter is formed on the counter substrate.

14. An organic EL panel as defined in claim 1, wherein
the plurality of pixels include pixels of four colors of red, green, blue, and white; and
the microresonators are provided in pixels of three colors of red, green, and blue, while microresonator is omitted in a white pixel.
